(19) United States
(12) Patent Application Publication
(10) Pub. No.: US 2007/0127533 A1
(43) Pub. Date: Jun. 7, 2007

(54) Long-wavelength vertical cavity surface emitting lasers having oxide aperture and method for manufacturing the same

(75) Inventors: Byueng Su Yoo, Daejeon (KR); Jay Roh, Daejeon (KR); Seong Ju Park, Daejeon (KR); Ki Hwang Lee, Daejeon (KR)

Correspondence Address: WILLIAM COLLARD;COLLARD & ROE, P.C., 1077 NORTHERN BOULEVARD, ROSLYN, NY, 11576, US

(73) Assignee: Raycan Co., Ltd.

(21) Appl. No.: 11/322,186

(22) Filed: Dec. 29, 2005

(30) Foreign Application Priority Data
Dec. 5, 2005 (KR) 10-2005-0117350

(51) Int. Cl. H01S 5/00

(52) U.S. Cl. 372/50.1; 372/50.11

(57) ABSTRACT

Disclosed herein is a vertical cavity surface emitting laser device. The laser device comprises a semiconductor lower mirror layer, a first semiconductor electrode layer, a gain-activation layer and a semiconductor anode layer sequentially grown on the compound semiconductor substrate, a re-growth pattern formed on the semiconductor anode layer to a width of 10˜100 μm and an etching depth equal to or less than the semiconductor anode layer by etching, a first anode semiconductor buffer layer grown at a low temperature on the pattern, a second anode semiconductor layer grown at the low temperature for formation of an oxide layer, an anode semiconductor layer for tunnel junction, a cathode semiconductor layer for tunnel junction, a second semiconductor electrode layer for injection of electrons, and an upper mirror layer formed on the second semiconductor electrode layer. With this structure, the laser device comprises an effective electric current confining structure.

### TECHNICAL FIELD

The present invention relates to a long-wavelength vertical cavity surface emitting laser device having an oxide aperture, and a method for manufacturing the same. More particularly, the present invention relates to a long-wavelength vertical cavity surface emitting laser device, which comprises a very effective electric current confining structure formed at a low temperature of 400° C. or less for a very short period of time, thereby solving problems, such as high temperature and long period of wet oxidation, difficulty in adjusting thickness/dimensions of layers, reduction in efficiency of the laser device caused by inherent scattering loss, and complicacy of conventional techniques, such as a process of forming an electric current confining structure in an air-gap, a process using an InAlAs oxide layer, an ion-implantation process, a wafer bonding process, etc.

### BACKGROUND ART

Generally, a vertical cavity surface emitting laser device has excellent properties of a low threshold current, and high optical fiber coupling efficiency resulting from a circular beam in comparison to a conventional edge emitting laser device. In addition, the vertical cavity surface emitting laser device has merits, such as easy production of a two-dimensional array, allowance of diode test in a wafer state, and mass productivity, which are also evaluated as merits of conventional electronic diodes. Consequently, the vertical cavity surface emitting laser device has been spotlighted as a diode, which can replace conventional edge-emitting laser diodes for optical communication networks and optical sensors in terms of its excellent performance and low price.

Technically, in order to manufacture the vertical cavity surface emitting laser device, it is necessary to provide a mirror layer having a high reflectance rate, a material having a high optical gain, and an effective current confinement structure, and the like. In particular, for a laser device, since light of different wavelengths must be emitted depending on applications, it is necessary to provide effective combinations of materials according to the applications.

For example, for an application of a wavelength of 850 nm, the vertical cavity surface emitting laser device is formed to comprise a semiconductor mirror layer having a high reflectance rate, and an activation layer of a material having a high optical gain on a GaAs substrate, and to have excellent thermal properties due to an electric current confining structure formed in the oxide layer using a combination of GaAs/AlGaAs. As a result, the vertical cavity surface emitting laser device has been successfully commercialized.

However, for applications of wavelengths of 1.3 μm and 1.5 μm, which are mainly used for communication, it is difficult to use GaAs/AlGaAs, and thus, the vertical cavity surface emitting laser device is generally formed using InGaAsP or InAlGaAs on an InP substrate. In this case, it is necessary to form a number of layers in order to achieve a high reflectance rate. In addition, quaternary materials such as InGaAsP or InAlGaAs results in a low thermal conductivity of about 1/10 that of binary materials such as GaAs, and have many problems caused by difficulty in provision of the effective current confinement structure.

Accordingly, various techniques have been attempted to solve these problems and to develop a long-wavelength vertical cavity surface emitting laser device. Methods for manufacturing the long-wavelength vertical cavity surface emitting laser device can be generally classified into a monolithic method by which the vertical cavity surface emitting laser device is manufactured using a process of manufacturing a semiconductor diode after simultaneously growing a mirror layer and an activation layer through semiconductor epitaxy growth, and a hybrid method by which the vertical cavity surface emitting laser device is manufactured by combining an optical gain-activation layer and a mirror layer which are grown separately. In the former case, there is merit in that, since the diode is manufactured after completing the structure through growth of the mirror layer and the activation layer, the manufacturing process is very simple. However, the monolithic method has disadvantages in that it is difficult to grow a thick mirror layer, and that quaternary materials are used, and therefore deteriorate the thermal properties. In the latter case, since the activation layer and the mirror layer are grown separately, it is possible to use the quaternary materials for the long-wavelength activation layer along with binary materials such as GaAs/AlAs for the mirror layer, so that excellent thermal and optical properties can be obtained. However, after the activation layer and the mirror layer are separately grown by the epitaxy growth, a complicated process (for example, a wafer bonding process) is used to combine these components into the structure for the vertical cavity surface emitting laser device, causing bonding defects. As a result, the hybrid method has problems of decreases in reliability and productivity along with an increase of manufacturing costs.

If the quaternary materials such as InGaAsP and InAlGaAs are employed due to the problem of AlGaAs, an ion-implantation process, a process for forming an electric current confining structure in an air gap, a process for forming a buried tunnel junction structure, a wafer bonding process, a process for forming an oxidation layer using an InAlAs layer, and the like are used in order to make an effective electric current confining structure. However, when manufacturing the long-wavelength vertical cavity surface emitting laser device, the ion-implantation process, the process for forming the electric current confining structure in the air gap, the process for forming the buried tunnel junction structure, the wafer bonding process, the process for forming an oxidation layer using an InAlAs layer and the like have problems in that a complicated process is required to form the electric current confining structure, and it is difficult to adjust the thickness of the electric current confining layer.

### DISCLOSURE

### TECHNICAL PROBLEM

The present invention has been made to solve the above problems, and it is an object of the present invention to provide a long-wavelength vertical cavity surface emitting laser device, and a method for manufacturing the same, which can allow easy manufacturing, and enhance reliability of the product.

### TECHNICAL SOLUTION

In order to achieve the above object, the present invention is conceived to solve the problems of the conventional technique. The conventional technique for forming the long-wavelength vertical cavity surface emitting laser device has problems in that it is formed by a complicated process, such as in the process of forming an AlGaAs oxide layer after separately growing a mirror layer and an activation layer on an InP-based material as metamorphic structures, and in that, if a process of bonding wafers to each other or by a process of forming an electric current confining structure in an air gap via selective etching is applied to form the laser device, an electric current confining layer has a restricted size and there occurs scattering loss related to the thickness of the layer. In particular, the present invention is conceived to solve the problem related to the process of forming the electric current confining structure, which has a significant influence on performance of the laser device upon operation of the vertical cavity surface emitting laser device. In the process of bonding the wafers between heterogeneous materials such as GaAs—InAlGaAs or in the process of growing the semiconductor layer with the metamorphic structure, since a bonding portion gives a very sensitive influence on electric or optical functions of the laser device, and contains defects inevitably formed therein, the process becomes complicated and lowers reliability of the product. In addition, the process of forming the electric current confining structure in the air gap has disadvantages of etching selectivity of the material caused by wet selective etching, scattering loss related to the thickness of the air gap, and low heat transfer caused by the air gap. The process of forming the electric current confining structure in an oxide layer via wet oxidation of InAlAs layer has problems in that since the oxidation step is performed at a high temperature of 600° C. for 6 hours or more, it requires high temperature and long period of time.

### ADVANTAGEOUS EFFECTS

In the vertical cavity surface emitting laser device of the invention, lattice defects can be minimized by growing a layer containing a sufficient content of material, for example, Al, based on stable homogeneous-materials and sensitive to wet oxidation, adjustment of the thickness of an electric current shielding layer can be easily obtained via low temperature re-growth and epitaxy growth, and the process can be performed at a low temperature of about 400° C. for a short period of time of several minutes by means of the step of oxidizing an AlGaAs layer. In particular, the vertical cavity surface emitting laser device of the invention comprises the AlGaAs oxide layer, so that it can be very easily manufactured with high reliability and stability.

### DESCRIPTION OF THE DRAWINGS

The foregoing and other objects and features of the present invention will be more clearly understood from the following detailed description taken in conjunction with the accompanying drawings, in which:

FIGS. 1 to 10 illustrate sequential steps of a method for manufacturing a long-wavelength vertical cavity surface emitting laser device in accordance with the present invention;

FIG. 1 is a cross-sectional view a semiconductor mirror layer, a semiconductor anode layer, an optical gain-activation layer, and a semiconductor cathode layer for injection of electric current on a compound semiconductor substrate in accordance with one embodiment of the present invention;

FIG. 2 is a cross-sectional view illustrating a pattern having a predetermined size formed on the epitaxy layer of FIG. 1 for re-growth by etching;

FIG. 3 is a cross-sectional view illustrating an anodic buffer layer grown at a low temperature, an anode semiconductor layer grown at a low temperature for formation of an oxide layer, an anode semiconductor layer and a cathode semiconductor layer for tunnel junction, and a semiconductor cathode layer sequentially formed on the resultant of FIG. 2;

FIG. 4 is a cross-sectional view illustrating a device mesa having a predetermined size by patterning and etching the resultant of FIG. 3;

FIG. 5 is a cross-sectional view illustrating a structure for an electric current confinement which can restrict current flow by forming an oxide layer on the structure obtained in FIG. 4 by a wet oxidation process;

FIG. 6 is a cross-sectional view illustrating a vertical cavity surface emitting laser device having a dielectric mirror layer and an ohmic contact layer for injection of electric current on the resultant of FIG. 5;

FIG. 7 is a cross-sectional view illustrating semiconductor layers including a semiconductor upper mirror layer re-grown on the structure of FIG. 2 in accordance with another embodiment of the present invention;

FIG. 8 is a cross-sectional view illustrating the step of forming a mesa structure for the upper mirror layer and a device mesa on the structure of FIG. 7 by etching;

FIG. 9 is a cross-sectional view illustrating another embodiment having an electric current confinement structure formed therein by the same wet oxidation process as that of FIG. 5; and

FIG. 10 is a cross-sectional view illustrating an embodiment formed by applying the method of FIG. 9 to the vertical cavity surface emitting laser device having the semiconductor upper mirror layer.

### MODE FOR INVENTION

Preferred embodiments of the present invention will be described in detail with reference to the accompanying drawings.

A method for manufacturing a long-wavelength vertical cavity surface emitting laser device in accordance with one embodiment of the present invention will be described as follows.

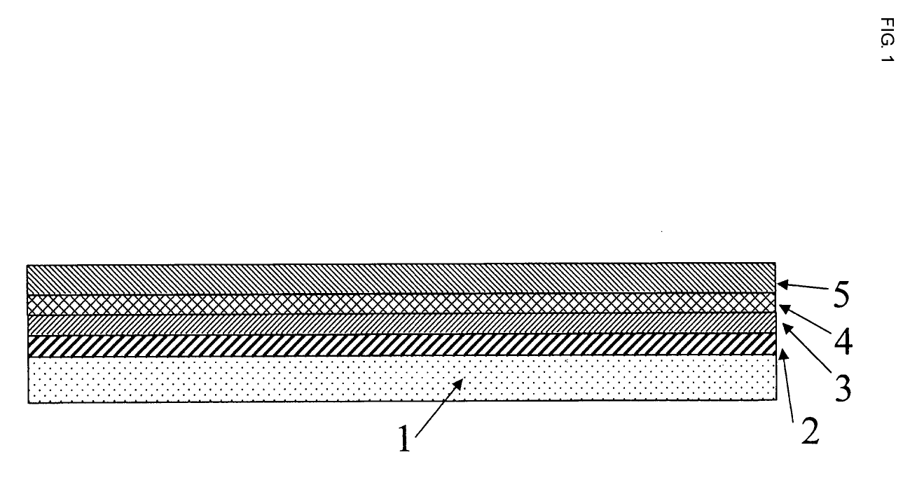

First, as shown in FIG. 1, in order to manufacture the long-wavelength vertical cavity surface emitting laser device of the invention, a semiconductor lower mirror layer 2 is grown on an InP substrate 1 by a compound-semiconductor epitaxy growth method, in which the semiconductor lower mirror layer 2 comprises InAlGaAs/InAlAs or InAlGaAs/InP. Then, a first semiconductor electrode layer 3 comprising n-InP, an optical gain-activation layer 4 constituted by an InAlGaAs multiple quantum-well layer, and a semiconductor anode layer 5 comprising p-InP are sequentially grown on the semiconductor lower mirror layer 2.

At this time, the n-InP and p-InP semiconductor electrode layers 3 and 5 serve as electrode layers for injection of electric current into the optical gain-activation layer 4 which is the InAlGaAs multiple quantum-well layer, and serve to dissipate heat with excellent thermal properties. The optical gain-activation layer 4 serves as a gain layer for generation of laser.

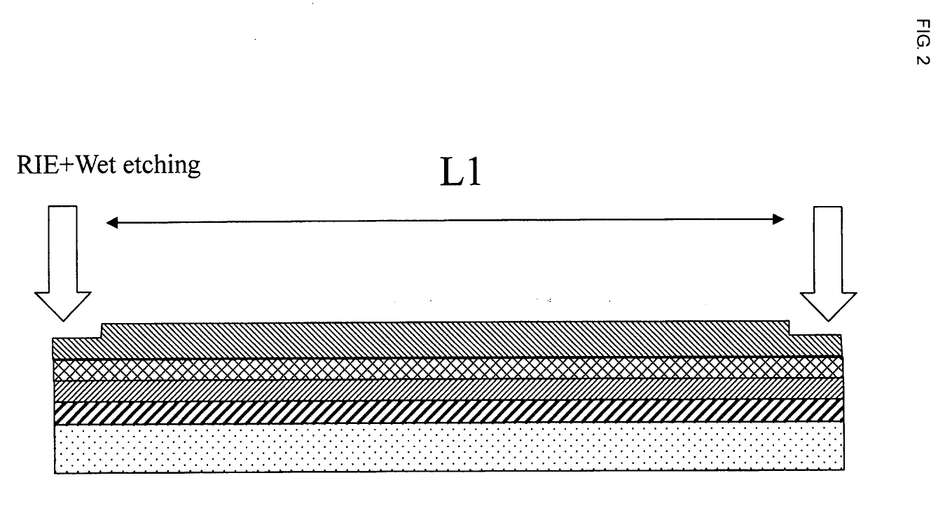

FIG. 2 shows the etching step preceding the re-growth step for forming the long-wavelength vertical cavity surface emitting laser device on the resultant of FIG. 1. In FIG. 2, the p-InP semiconductor anode layer 5 is etched to have a thin pattern having a length L1 thereon.

Etching of the semiconductor anode layer 5 is performed using a SiOx or SiNx mask by wet-etching or dry-etching so as to minimize damage of the semiconductor anode layer 5, which can be caused by the etching.

In order to ensure sufficient relaxation of a lattice during low-temperature re-growth of a lattice mismatch layer at the following step, the etching of the semiconductor anode layer 5 must be performed such that an etching width is in the range of 10˜100 μm, and an etching depth is equal to or less than the thickness of the semiconductor anode layer 5.

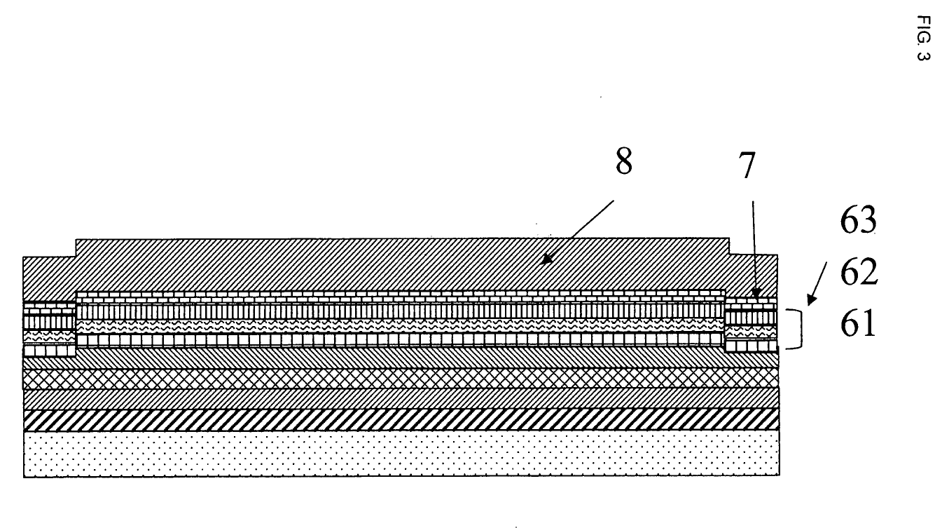

In FIG. 3, the structure for low-temperature re-growth is prepared. In order to form the long-wavelength vertical cavity surface emitting laser device of the invention, a first anode (i.e. positive electrode) semiconductor buffer layer 61 formed of p-InAlAs and grown at a low temperature, a second anode semiconductor layer 62 formed of p-AlGaAs and grown at the low temperature for formation of an oxide layer, an anode semiconductor layer 63 formed of p-InAlAs for tunnel junction, a cathode (i.e. negative electrode) semiconductor layer 7 formed of n-InP for tunnel junction, and a second semiconductor electrode layer 8 formed of n-InP for injection of electrons are sequentially grown on the p-InP semiconductor anode layer 5. Each layer is grown to a resonance thickness in consideration of an oscillation wavelength of the overall structure of the laser device. At this time, unlike the structure shown in FIG. 1, the first anode semiconductor buffer layer 61 formed of p-InAlAs is grown at the low growth temperature. Typically, the first anode semiconductor buffer layer 61 is grown to a thickness of several dozens of nm at a temperature of about 350˜550° C. With the first anode semiconductor buffer layer 61 grown as described above, lattice mismatch between an InP-based material and the second anode semiconductor layer 62 grown on the first anode semiconductor buffer layer 61 can be alleviated.

The p-AlGaAs based second anode semiconductor layer 62 for formation of the oxide layer is typically grown to a thickness of 30 nm or less at the low temperature, and has an Al content adjusted in the range of 90˜100% according to the condition of forming the oxide layer.

The anode semiconductor layer 63 for tunnel junction, and the cathode semiconductor layer 7 for tunnel junction are grown on the second anode semiconductor layer 62 to form a tunnel junction layer, in which the anode semiconductor layer 63 is formed of p⁺⁺-InAlAs, and the cathode semiconductor layer 7 is formed of n⁺⁺-InP with a doping concentration of 5×10¹⁹ or more. At this time, as the doping concentration is increased, the tunnel junction layer operating in a reverse direction upon operation of the laser device has a lower resistance. Finally, the second semiconductor electrode layer 8 formed of n-InP for injection of electric current is formed, and constitutes an electrode.

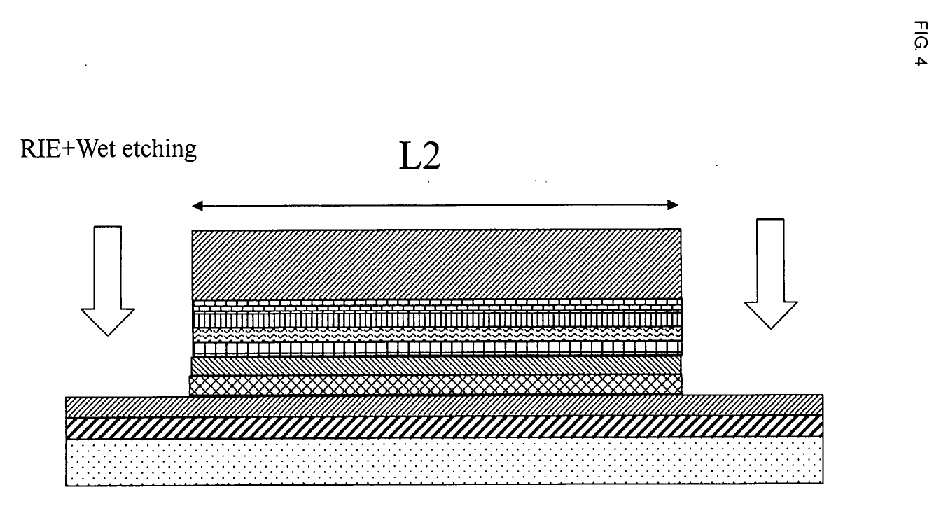

FIG. 4 shows the step of forming a device mesa by etching the resultant formed by the re-growth. The device mesa having a length L2 is formed by wet-etching or gas-etching which uses a mixture of CH₄—H₂—Ar—Cl₂. At this step, etching is performed to an extent that the first semiconductor electrode layer 3 formed of n-InP is exposed. Typically, the length L2 is smaller than the length L1 so that the device mesa is positioned inside the pattern of the length L1.

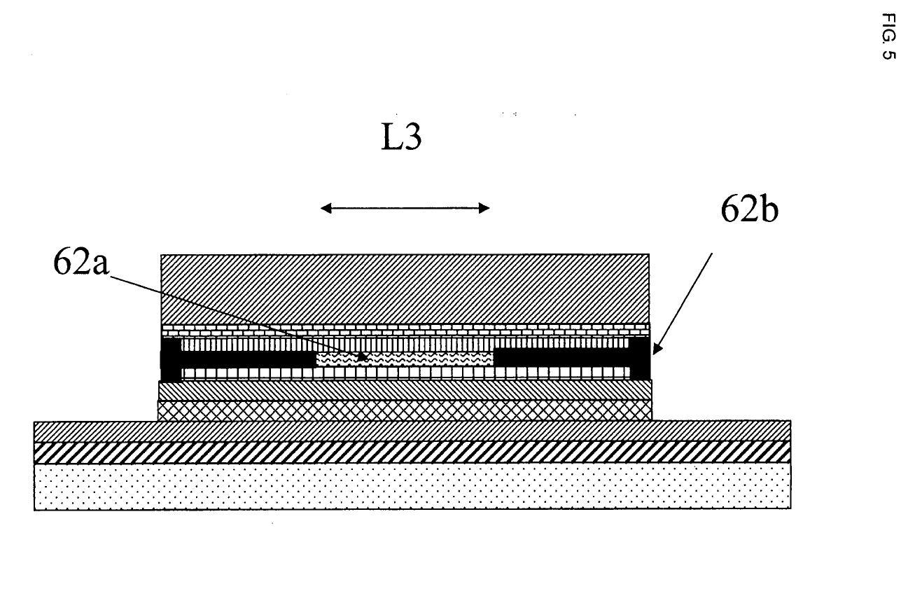

FIG. 5 shows one example of a process for forming an oxide layer on the mesa structure. As in an 850 nm vertical cavity surface emitting laser device based on AlGaAs, the AlGaAs layer interposed between the semiconductor layers, i.e., the second anode semiconductor layer 62 is oxidized in a wet atmosphere containing nitrogen and vapor at a temperature of 400° C., and forms an electric current shielding layer 62b composed of an AlOx oxide layer, which forms an electric current confining structure in the laser device of the invention. In particular, according to the present invention, since the speed of forming the oxide layer in AlGaAs significantly depends on the Al content, the Al content is in the range of 90˜100%. As a result, not only oxidization selectivity with respect to other exposed semiconductor layers is increased, but also processing temperature and period are optimized. At this time, when the mesa structure has the length L2, an electric current injection layer 62a has a length L3, which is typically smaller than L2.

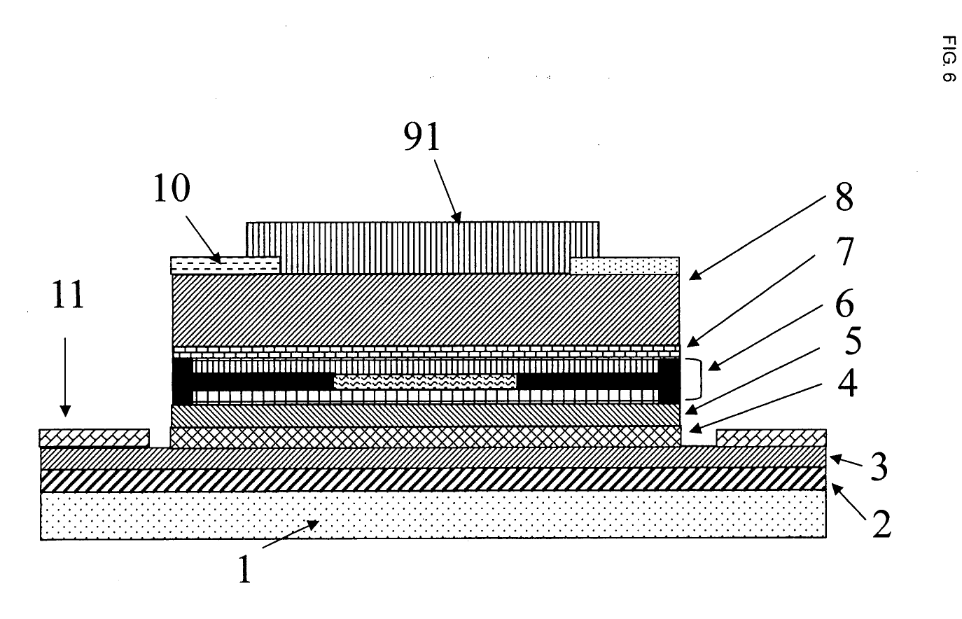

FIG. 6 shows a hybrid-type vertical cavity surface emitting laser device formed by a method according to one embodiment of the present invention.

This vertical cavity surface emitting laser device is formed by forming an oxide aperture for injection of electric current through wet etching, followed by respectively forming metallic electrode layers 10 and 11 for injection of electric current on the first and second semiconductor electrode layers 3 and 8, and then forming a dielectric mirror layer 91.

In the case of n-InP, the metallic electrode layers 10 and 11 are formed of an AuGe/Ni/Au layer or a Cr/Au layer, and are annealed to form ohmic contacts.

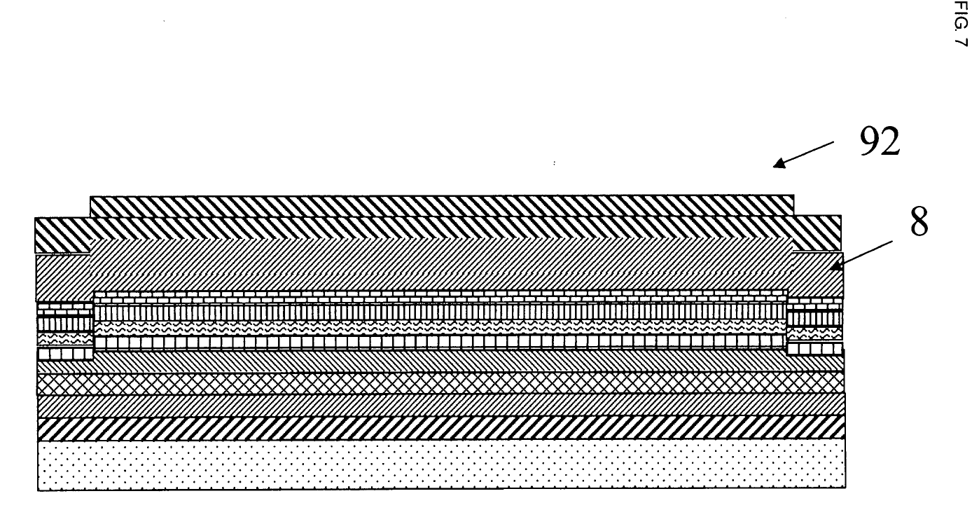

FIG. 7 shows a vertical cavity surface emitting laser device formed by a method according to another embodiment of the present invention. Unlike the vertical cavity surface emitting laser device shown in FIG. 6, a semiconductor mirror layer 92 is formed as the upper mirror layer on the structure of FIG. 1 during the epitaxy re-growth step shown in FIG. 2. The semiconductor mirror layer 92 is formed to a multi-layer semiconductor such as an InAlGaAs/InAlAs layer or an InAlGaAs/InP layer as in the lower mirror layer 2.

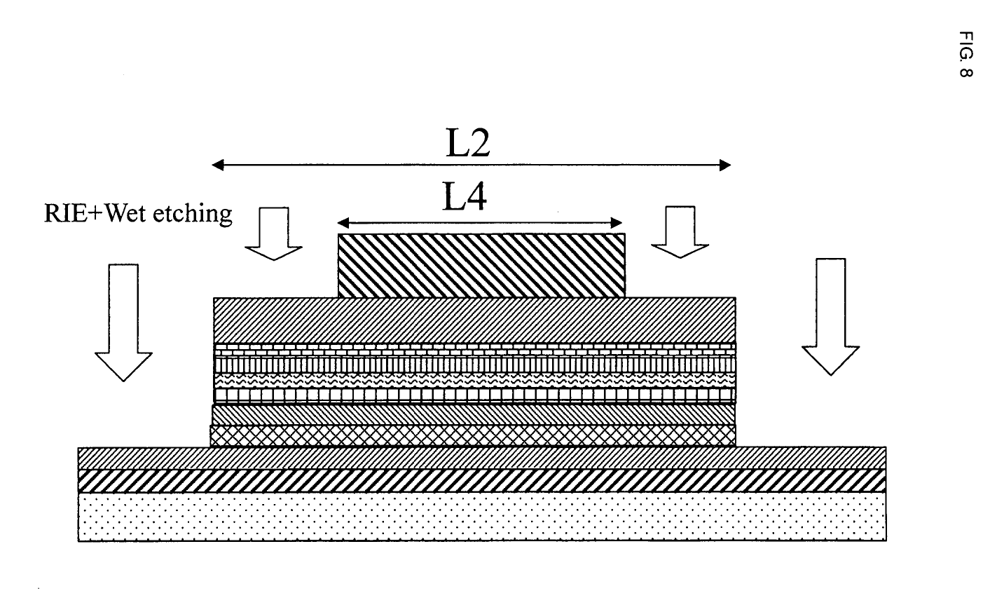

FIG. 8 shows the step of forming a mesa structure from the re-grown epitaxy structure of FIG. 7. First, in order to define the semiconductor mirror layer 92 at an upper portion of the diode, etching of the re-grown epitaxy structure shown in FIG. 7 is performed to form a primary mesa structure having a length L4 while exposing the first semiconductor layer 8 formed at a lower portion. Next, etching is performed to form a secondary mesa structure having a length L2 while exposing the first semiconductor electrode layer 3 formed at the lower portion. At this time, this step is performed such that the primary mesa structure having the length L4 of the semiconductor mirror layer 92 is located inside the secondary mesa structure having the length L2, and such that the semiconductor diode comprises an anode semiconductor layer 62 formed of an AlGaAs layer re-grown at a low temperature inside the secondary mesa structure.

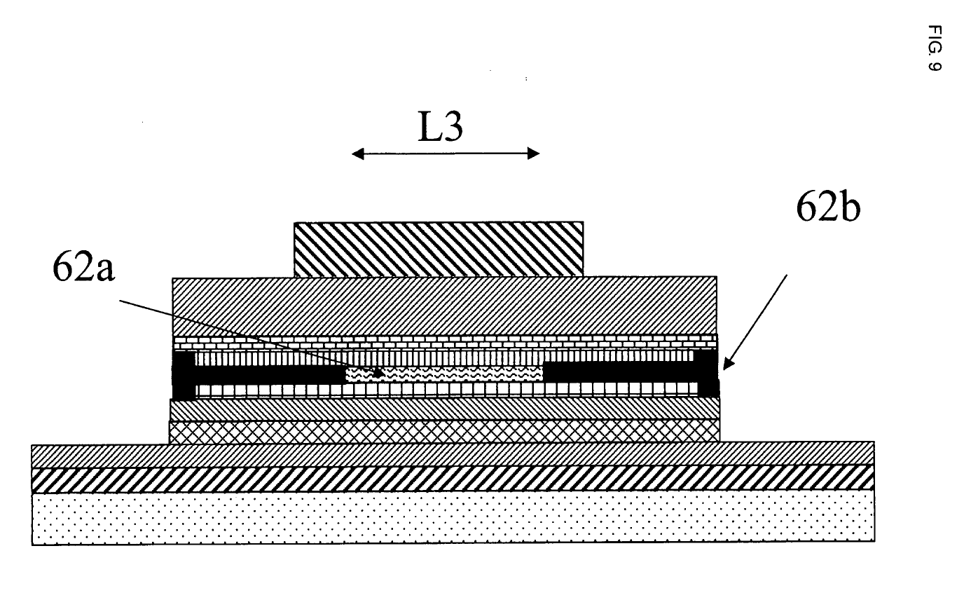

FIG. 9 shows an exemplary process for oxidizing the anode semiconductor layer 62 through wet oxidation for the mesa structure of FIG. 8. At this time, the electric current injection aperture 62a has a length L3 smaller than the length L4 of the mesa structure on the semiconductor mirror layer 92 formed at the upper portion.

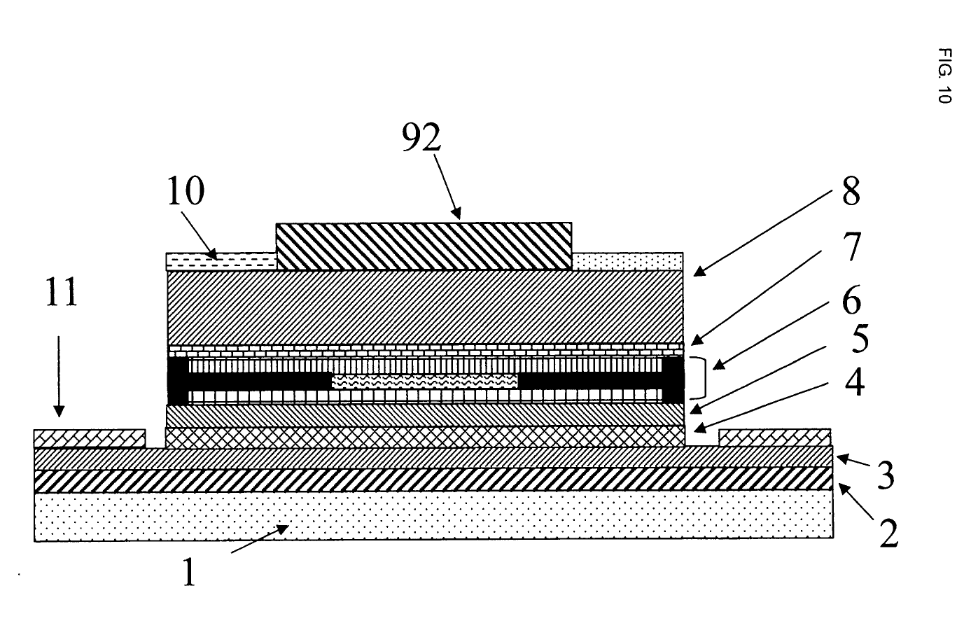

FIG. 10 shows a monolithic vertical cavity surface emitting laser device which is completely formed after forming the oxide aperture at the step shown in FIG. 9. In FIG. 10, the metallic electrode layers 10 and 11 are deposited on the first and second electrode layers 3 and 8 formed at upper and lower portions of the semiconductor diode. Electric current injected through the upper metallic layer 10 travels in the form of electrons through the second semiconductor electrode layer 8 for injection of electrons, and is then converted to the form of holes after tunneling through the cathode semiconductor layer 7 for tunnel junction. Then, the holes are restricted by the electric current shielding layer 62b, injected to the gain-activation layer 4 through the semiconductor anode layer 5 via the electric current injection aperture having the length L3, and recombined with electrons induced to the first semiconductor electrode layer 3 formed at the lower portion of the semiconductor diode, thereby generating laser.

Functions of the vertical cavity surface emitting laser device having the oxide aperture of the present invention will be described with reference to FIG. 6 or 10.

When electricity is applied to the vertical cavity surface emitting laser device with the metallic electrode layer 10 connected with a cathode of a power source, and with the metallic electrode layer 11 connected with an anode of the power source, electric current is injected to the electric current injection layer 62a through the second semiconductor electrode layer 8, the cathode semiconductor layer 7 for tunnel junction, and the anode semiconductor layer 63 for tunnel junction. At this time, since the electric current shielding layer 62b provided by forming the oxide layer at both sides of the electric current injection layer 62a is the dielectric layer, electric current does not flow through the electric current shielding layer 62b, and flows only to the electric current injection aperture L3.

As such, the electric current flows only to the electric current injection aperture L3, and is then injected to the gain activation layer 4 through the semiconductor buffer layer 61 and the semiconductor anode layer 5. Accordingly, it is possible to allow electric current to selectively flow only to the electric current injection aperture L3 from among the overall components. Thus, the vertical cavity surface emitting laser device of the invention generates light in the region of the electric current injection aperture L3, amplifies the light via repetitious reflection between the upper mirror layers 91 and 92 and the lower mirror layer 2, and then emits the amplified light, i.e., laser, above the upper mirror layers 91 and 92 and below the lower mirror layers 2.

As such, the vertical cavity surface emitting laser device having the oxide aperture of the present invention can be easily manufactured, reduced in scattering loss, and is highly efficient.

### INDUSTRIAL APPLICABILITY

As apparent from the above description, the vertical cavity surface emitting laser device is formed by sequentially growing a semiconductor lower mirror layer, a first semiconductor electrode layer, an activation layer, a p-InP semiconductor electrode layer on an InP substrate, patterning the p-InP semiconductor electrode layer to a predetermined size for re-growth, forming a p-InAlAs buffer layer, a p-AlGaAs layer for formation of oxide layer, p⁺⁺-InAlGaAs and n⁺⁺-InP tunnel junction layers, and an n-InP upper electrode layer via a low-temperature re-growth process, and forming a dielectric multilayer or a semiconductor multi-mirror layer as an upper mirror layer thereon. As such, although the long-wavelength vertical cavity surface emitting laser device of the invention is based on InP—InAlGaAs, it also comprises the AlGaAs oxide layer. Thus, by forming a very effective electric current confining structure at a low temperature of 400° C. for a very short period of time, advantageous effects can be achieved, which prevents a reduction in efficiency of the laser device caused by difficulty in adjusting thickness/dimensions, inherent scattering loss, complicacy of the process, high temperature and long period wet oxidation, and the like in conventional techniques, such as the process of forming the electric current confining structure in an air-gap, the process using the InAlAs oxide layer, the ion-implantation process, the wafer bonding process, etc. Consequently, the vertical cavity surface emitting laser device of the invention can be manufactured in mass production with a low price while remarkably improving the thermal properties of the diode.

It should be understood that the embodiments and the accompanying drawings have been described for illustrative purposes and the present invention is limited by the following claims. Further, those skilled in the art will appreciate that various modifications, additions and substitutions are allowed without departing from the scope and spirit of the invention as set forth in the accompanying claims.

1. A vertical cavity surface emitting laser device, comprising:
a compound semiconductor substrate;
a semiconductor lower mirror layer, a first semiconductor electrode layer, a gain-activation layer and a semiconductor anode layer sequentially grown on the compound semiconductor substrate;
a re-growth pattern formed on the semiconductor anode layer to a width of 10˜100 μm and an etching depth equal to or less than semiconductor anode layer by etching;
a first anode semiconductor buffer layer grown at a low temperature on the pattern;
a second anode semiconductor layer grown at the low temperature for formation of an oxide layer;
an anode semiconductor layer for tunnel junction;
a cathode semiconductor layer for tunnel junction;
a second semiconductor electrode layer for injection of electrons; and
an upper mirror layer formed on the second semiconductor electrode layer.

2. The laser device according to claim 1, wherein the upper mirror layer comprises InP/InAlGaAs or InAlAs/InAlGaAs.

3. The laser device according to claim 1, wherein the upper mirror layer is a dielectric mirror layer.

4. The laser device according to claim 1, wherein the gain-activation layer comprises InAlGaAs.

5. The laser device according to claim 1, wherein the second anode semiconductor layer comprises AlGaAs or Al sensitive to oxidation.

6. A method for manufacturing a vertical cavity surface emitting laser device, comprising the steps of:
sequentially growing a semiconductor lower mirror layer, a first semiconductor electrode layer, a gain-activation layer, and a semiconductor anode layer sequentially on a compound semiconductor substrate;
forming a re-growth pattern on the semiconductor anode layer to a width of 10˜100 μm and an etching depth equal to or less than the semiconductor anode layer by etching;
sequentially forming a first anode semiconductor buffer layer grown at a low temperature, a second anode semiconductor layer grown at the low temperature for formation of an oxide layer, an anode semiconductor layer for tunnel junction, a cathode semiconductor layer for tunnel junction, and a second semiconductor electrode layer for injection of electrons on the re-growth pattern; and
forming an upper mirror layer on the second semiconductor electrode layer.

7. The method according to claim 6, wherein the low temperature is in the range of 350˜550° C.
